(19) United States
(12) Patent Application Publication
(10) Pub. No.: US 2022/0397820 A1
(43) Pub. Date: Dec. 15, 2022

(54) PHOTOMASK, METHOD OF MANUFACTURING ARRAY SUBSTRATE, AND DISPLAY PANEL

(71) Applicant: TCL China Star Optoelectronics Technology Co., Ltd., Shenzhen, Guangdong (CN)

(72) Inventors: Xiaofang TAN, Shenzhen, Guangdong (CN); Wei HE, Shenzhen, Guangdong (CN)

(73) Assignee: TCL China Star Optoelectronics Technology Co., Ltd., Shenzhen, Guangdong (CN)

(21) Appl. No.: 17/263,958

(22) PCT Filed: Dec. 31, 2020
(86) PCT No.: PCT/CN2020/141925

§ 371 Date: Jan. 28, 2021

(30) Foreign Application Priority Data
Dec. 28, 2020 (CN) 202011578685.X

(51) Int. Cl. G03F 1/40; H01L 27/12; H01L 51/56; H01L 27/32

(52) U.S. Cl. CPC G03F 1/40; H01L 27/1288; H01L 27/127; H01L 51/56; H01L 27/1251; H01L 27/3244; H01L 2227/323

(57) ABSTRACT

A photomask, a method of manufacturing an array substrate, and a display panel are provided. The photomask includes a photomask line of a first conductive portion, a photomask line of a second conductive portion spaced apart from the photomask line of the first conductive portion, and a bridging line. Two opposite ends of the bridging line are respectively connected to the photomask line of the first conductive portion and the photomask line of the second conductive portion, and a width of the bridging line is less than a preset width.

### FIELD OF INVENTION

The present invention relates to the field of display technologies and in particular to a photomask, a method of manufacturing an array substrate, and a display panel.

### BACKGROUND OF INVENTION

With continuous development of display panel technologies, people have higher requirements for display quality, which leads to more complex circuit designs of array substrates and more crossovers in display panels. Especially in border circuit regions outside effective display regions, the circuit designs are dense. Correspondingly, photomask designs used for patterning processes are also more complicated. Pattern pitches are too small, causing narrow-pitch regions in photomasks to be easily damaged by static electricity during exposure processes, so that lines that need to be spaced in original designs are short-circuited, resulting in defects in the display panels.

### SUMMARY

The present invention provides a photomask, a method of manufacturing an array substrate, and a display panel, which can effectively reduce risks of electrostatic damage during a manufacturing process and improve product yield.

In order to solve the above problems, in a first aspect, the present invention provides a photomask. The photomask comprises:

a photomask line of a first conductive portion;

a photomask line of a second conductive portion spaced apart from the photomask line of the first conductive portion; and

a bridging line, wherein two opposite ends of the bridging line are respectively connected to the photomask line of the first conductive portion and the photomask line of the second conductive portion, and a width of the bridging line is less than a preset width.

In the photomask provided by an embodiment of the present invention, the photomask line of the first conductive portion comprises a plurality of photomask sub-lines of the first conductive portion spaced apart from each other, and each of the photomask sub-lines of the first conductive portion is connected to the photomask line of the second conductive portion via the bridging line.

In the photomask provided by an embodiment of the present invention, a shape of the bridging line is a straight line, a broken line, or a curved line.

In the photomask provided by an embodiment of the present invention, the width of the bridging line is less than 1.5 microns.

In the photomask provided by an embodiment of the present invention, the width of the bridging line ranges from 0.5 to 1.0 microns.

In the photomask provided by an embodiment of the present invention, the bridging line is a uniform line of equal width.

In the photomask provided by an embodiment of the present invention, the bridging line is a non-uniform line with unequal width, and a width of at least one portion of the bridging line is less than the preset width.

In a second aspect, the present invention provides a method of manufacturing an array substrate. The method comprises a step of forming a conductive layer on the array substrate, and the step of forming the conductive layer specifically comprises following steps:

S10: forming a metal layer;

S20: forming a photoresist layer on the metal layer;

S30: exposing the photoresist layer under a cover of a photomask to form a patterned photoresist layer, wherein the photomask comprises:

a photomask line of a first conductive portion;

a photomask line of a second conductive portion spaced apart from the photomask line of the first conductive portion; and

a bridging line, wherein two opposite ends of the bridging line are respectively connected to the photomask line of the first conductive portion and the photomask line of the second conductive portion, and a width of the bridging line is less than a preset width;

S40: etching the metal layer to form the conductive layer under a cover of the patterned photoresist layer, wherein the conductive layer comprises the first conductive portion and the second conductive portion disposed at intervals; and

S50: stripping and removing the patterned photoresist layer.

In the method of manufacturing the array substrate provided by the embodiment of the present invention, in the step S10, the metal layer is formed by sputtering by a physical vapor deposition process.

In the method of manufacturing the array substrate provided by the embodiment of the present invention, in the step S20, the photoresist layer is formed by a positive photoresist material.

In the method of manufacturing the array substrate provided by the embodiment of the present invention, in the step S30, a shape of the bridging line is a straight line, a broken line, or a curved line.

In the method of manufacturing the array substrate provided by the embodiment of the present invention, the conductive layer is a gate metal layer.

In the method of manufacturing the array substrate provided by the embodiment of the present invention, the conductive layer is a source-drain metal layer.

In the method of manufacturing the array substrate provided by the embodiment of the present invention, in the photomask, the photomask line of the first conductive portion is a photomask line of an electrostatic sharing electrode line, the photomask line of the second conductive portion is a photomask line of a gate of an electrostatic ring thin film transistor, so that the first conductive portion is the gate of the electrostatic ring thin film transistor, and the second conductive portion is the electrostatic sharing electrode line.

In the method of manufacturing the array substrate provided by the embodiment of the present invention, the photomask line of the gate of the electrostatic ring thin film transistor comprises a plurality of photomask lines of gate islands of the electrostatic ring thin film transistor spaced apart from each other, each of the photomask lines of the gate islands of the electrostatic ring thin film transistor is connected to the photomask line of the electrostatic sharing electrode line via the bridging line, so that the formed gate of the electrostatic ring thin film transistor in a first conductive layer comprises a plurality of gate islands of the electrostatic ring thin film transistor spaced apart from each other.

In the method of manufacturing the array substrate provided by the embodiment of the present invention, the photomask further comprises photomask lines of a peripheral line spaced apart from the photomask lines of the electrostatic sharing electrode line, and the photomask line of the peripheral line is connected to the photomask line of the electrostatic sharing electrode line via the bridging line.

In the method of manufacturing the array substrate provided by the embodiment of the present invention, the photomask line of the peripheral line is disposed on a side of the photomask line of the electrostatic sharing electrode line and perpendicular to the photomask line of the electrostatic sharing electrode line.

In a third aspect, the present invention further provides a display panel. The display panel comprises an array substrate, which is formed by the above-mentioned method of manufacturing the array substrate.

In the display panel provided by the embodiment of the present invention, the display panel is a liquid crystal display panel, an OLED display panel, or a Micro-LED display panel.

### Beneficial Effect

The present invention provides a photomask, a method of manufacturing an array substrate, and a display panel. The photomask has a special structure design, which can effectively reduce risks of abnormal patterns caused by electrostatic damage to the photomask during exposure processes. Specifically, the photomask comprises a photomask line of a first conductive portion and a photomask line of a second conductive portion that are spaced apart from each other, and a bridging line is further added to connect the photomask line of the first conductive portion and the photomask line of the second conductive portion to provide a path for electrostatic discharge, which effectively reduces risks of electrostatic damage due to a small distance between the photomask line of the first conductive portion and the photomask line of the second conductive portion, which in turn leads to abnormalities in formed patterns, so as to improve yield of formed array substrates and display panels.

### DESCRIPTION OF DRAWINGS

In order to more clearly illustrate the embodiments or the technical solutions in the prior art, a brief introduction of the drawings used in the embodiments or the prior art description will be briefly described below. Obviously, the drawings in the following description are only some of the embodiments of the invention, and those skilled in the art can obtain other drawings according to the drawings without any creative work.

FIG. 1 is a schematic view of a planar structure of a photomask provided by an embodiment of the present invention.

FIG. 2 is a schematic view of a planar structure of another photomask provided by an embodiment of the present invention.

FIG. 3 is a schematic view of a manufacturing process of a conductive layer in a method of manufacturing an array substrate provided by an embodiment of the present invention.

FIG. 4 is a schematic view of a principle of patterning of the conductive layer in the method of manufacturing the array substrate provided by the embodiment of the present invention.

FIG. 5 is a schematic view of a planar structure of a photomask used in the method of manufacturing the array substrate provided by the embodiment of the present invention.

FIG. 6 is a schematic view of a planar structure of the array substrate manufactured in the method of manufacturing the array substrate provided by the embodiment of the present invention.

FIG. 7 is a detailed enlarged view of a region B1 in FIG. 3 provided by an embodiment of the present invention.

FIG. 8 is a schematic view of a planar structure of another photomask used in the method of manufacturing the array substrate provided by the embodiment of the present invention.

### DETAILED DESCRIPTION OF EMBODIMENTS

The following will clearly and completely describe the technical solutions in the embodiments of the present invention with reference to the drawings in the embodiments of the present invention. Obviously, the described embodiments are only a part of the embodiments of the present invention, rather than all the embodiments. Based on the embodiments in the present invention, all other embodiments obtained by those skilled in the art without creative work are within the protection scope of the present invention.

In the description of the present invention, it is to be understood that the terms “center,” “longitudinal,” “lateral,” “length,” “width,” “thickness,” “upper,” “lower,” “front,” “rear,” “left,” “right,” “vertical,” “horizontal,” “top,” “bottom,” “inner,” “outer,” “clockwise,” “counterclockwise,” and the like are used in the orientations and positional relationships indicated in the drawings for convenience in describing the present invention and for simplicity in description, and are not intended to indicate or imply that the referenced devices or elements must have a particular orientation, be constructed in a particular orientation, and be operated in a particular manner, and are not to be construed as limiting the present invention. Furthermore, the terms “first” and “second” are used for descriptive purposes only and are not to be construed as indicating or implying relative importance or implicitly indicating the number of technical features indicated. Thus, features defined as “first”, “second”, may explicitly or implicitly include one or more of the described features. In the description of the present application, “plurality” means two or more unless specifically limited otherwise.

In the present invention, the term “exemplary” is used to mean “used as an example, illustration, or illustration.” Any embodiment described as “exemplary” in the present invention is not necessarily to be construed as more preferred or advantageous than other embodiments. In order to enable any person skilled in the art to implement and use the present invention, the following description is given. In the following description, the invention sets out details for the purpose of explanation. It should be understood that those of ordinary skill in the art may recognize that the present invention can be implemented even without using these specific details. In other examples, well-known structures and processes will not be elaborated in detail to avoid unnecessary details that obscure the description of the present invention. Therefore, the present invention is not intended to be limited to the illustrated embodiments but should be consistent with the widest scope consistent with the principles and features disclosed in the present invention.

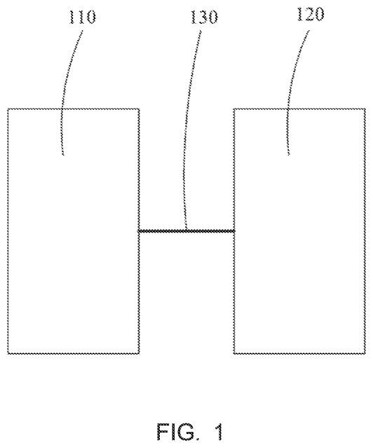

An embodiment of the present invention provides a photomask. With reference to a schematic view of a planar structure of the photomask provided in FIG. 1, the following detailed description is given:

The photomask comprises:

a photomask line of a first conductive portion 110;

a photomask line of a second conductive portion 120 spaced apart from the photomask line of the first conductive portion 110; and

a bridging line 130. Two opposite ends of the bridging line 130 are respectively connected to the photomask line of the first conductive portion 110 and the photomask line of the second conductive portion 120, and a width of the bridging line 130 is less than a preset width. It should be explained that the preset width described here is determined by accuracy of exposure equipment used during exposure. That is, the bridging line 130 is less than the accuracy of the exposure equipment used, and the exposure equipment cannot recognize the bridging line. Therefore, the added bridging line will not affect final patterns as a result of patterning.

As a result, by disposing the bridging line to connect the two photomask lines with a relatively short distance in a region where the photomask lines are densely arranged to provide a charge transfer channel, it can effectively reduce risks of abnormal patterns caused by electrostatic damage to the photomask during an exposure process. Meanwhile, since the width of the bridging line is less than the preset width, it will not affect a shape of a conductive layer obtained by final patterning.

In addition, accuracy of a current exposure equipment used for display panels is usually 1.5 μm, so the width of the bridging line is less than 1.5 μm. In order to further ensure that it will not affect actual patterns, the width of the bridging line usually ranges from 0.5 μm to 1.0 μm. Of course, with the iteration of technologies, this data will also change, and the present invention does not specifically limit thereto.

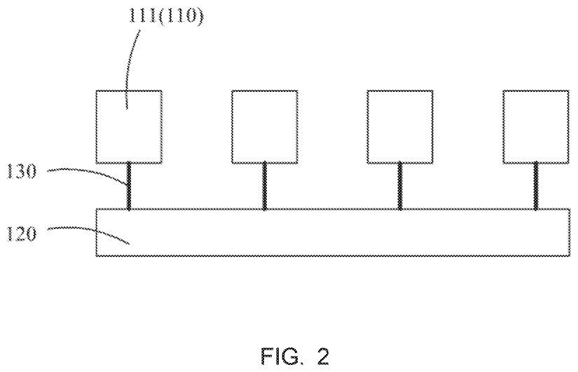

In some embodiments, according to actual exposure requirements, a structure of the photomask is usually more complicated. For example, please refer to a schematic view of a planar structure of another photomask provided in FIG. 2. The photomask line of the first conductive portion 110 comprises a plurality of photomask sub-lines of the first conductive portion 111 spaced apart from each other, and each of the photomask sub-lines of the first conductive portion 111 is connected to the photomask line of the second conductive portion 120 via at least one of the bridging lines 130. Of course, according to requirements, the photomask line of the second conductive portion may also comprise a plurality of photomask sub-lines of the second conductive portion spaced apart from each other, which will not be repeated here, and those skilled in the art should easily understand.

In some embodiments, according to actual shapes and relative positions of the photomask line of the first conductive portion 110 and the photomask line of the second conductive portion 120, a shape of the bridging line 130 may be a straight line, a broken line, or a curved line.

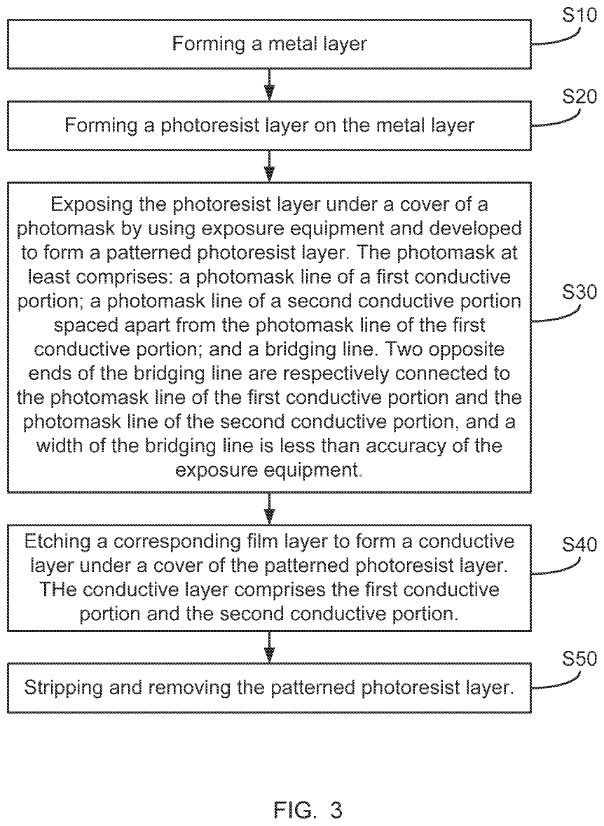

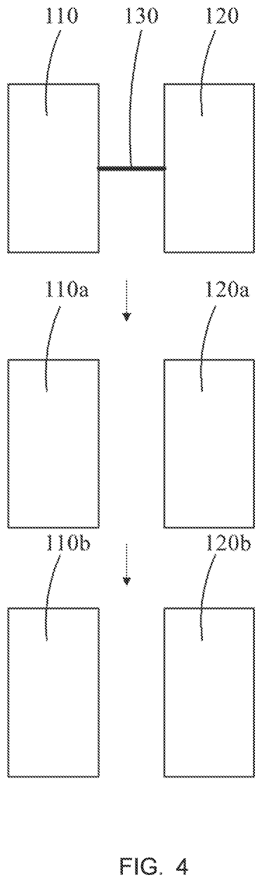

An embodiment of the present invention further provides a method of manufacturing an array substrate. Combining a schematic view of a manufacturing process provided in FIG. 3 and a schematic view of a principle of patterning in the method of manufacturing provided in FIG. 4, the following detailed description is given:

The method of manufacturing comprises forming a conductive layer on the array substrate, wherein steps of forming the conductive layer specifically comprises:

S10: forming a metal layer corresponding to materials, wherein the metal layer is usually a film layer on an entire surface sputtered by a physical vapor deposition process;

S20: forming a photoresist layer on the metal layer;

S30: exposing the photoresist layer under cover of the photomask by using the exposure equipment and developing to form a patterned photoresist layer. It can be understood that a photoresist material used here is a positive photoresist material. That is, an exposed portion that is not covered by the photomask is removed by a developer, so that a pattern of the patterned photoresist layer formed is approximately same as a pattern of the photomask. Specifically, referring to FIG. 4, the photomask at least comprises:

the photomask line of the first conductive portion 110;

the photomask line of the second conductive portion 120 spaced apart from the photomask line of the first conductive portion 110; and

the bridging line 130. The two opposite ends of the bridging line 130 are respectively connected to the photomask line of the first conductive portion 110 and the photomask line of the second conductive portion 120, and the width of the bridging line 130 is less than the accuracy of the exposure equipment. As a result, since the width of the added bridging line is less than the accuracy of the used exposure equipment, i.e., the exposure equipment cannot recognize the bridging line, the patterned photoresist layer actually formed only comprises a photoresist line of the first conductive portion 110a corresponding to the photomask line of the first conductive portion 110 and a photoresist line of the second conductive portion 120a corresponding to the photomask line of the second conductive portion 120, without forming a shape corresponding to the bridging line 130.

S40: etching a corresponding film layer to form the conductive layer under cover of the patterned photoresist layer. It can be understood that a portion not covered by the patterned photoresist layer is etched and removed, so that the formed conductive layer comprises a first conductive portion 110b and a second conductive portion 120b disposed at intervals; and

S50: stripping and removing the patterned photoresist layer.

In the method of manufacturing provided in this embodiment, the above-mentioned specially designed photomask is used to pattern the conductive layer. By disposing the bridging line to connect the two photomask lines with a relatively short distance in the region where the photomask lines are densely arranged to provide the charge transfer channel, it can effectively reduce the risks of abnormal patterns caused by the electrostatic damage to the photomask during the exposure process. Meanwhile, since the width of the bridging line is less than the accuracy of the exposure equipment, it will not affect the shape of the conductive layer obtained by final patterning.

It is understandable that, in the method of manufacturing provided in the embodiment, the forming of the array substrate usually comprises overlapping and forming a plurality of conductive layers, active layers, and insulating layers to form a thin film transistor structure as a driving switch. Patterning solutions using the above-mentioned specially designed photomask can be applied to patterning processes of any film layer in the process of manufacturing the array substrate, especially conductive layers with dense lining design to solve problems of electrostatic damage caused by dense lining in the photomask during exposure process, which in turn leads to abnormal patterns of the film layers formed after patterning.

Moreover, in the method of manufacturing provided in this embodiment, the photomask only shows the photomask line of the first conductive portion and the photomask line of the second conductive portion as examples to express an intention of the invention more clearly. In an actual method of manufacturing, according to design requirements, the photomask certainly comprises other photomask lines, which should be easily understood by those skilled in the art.

In some embodiments, the bridging lines can be uniform lines with equal width everywhere, or non-uniform lines with unequal widths. When the bridging lines are non-uniform lines, theoretically speaking, there only needs to be any one place where a width of the line is less than the accuracy of the exposure equipment to ensure that in an actually formed conductive layer, the first conductive portion 110b and the second conductive portion 120b formed corresponding to the photomask line of the first conductive portion 110 and the photomask line of the second conductive portion 120 do not short-circuit.

In some embodiments, the method of manufacturing the array substrate generally comprises forming a gate metal layer, a first insulating layer, a source-drain metal layer, a second insulating layer, and an electrode layer in sequence. The electrode layer is usually a pixel electrode layer (when applied to a liquid crystal display panel) or an anode layer (when applied to an organic light-emitting diode display panel). The conductive layer is at least one of the gate metal layer or the source-drain metal layer. That is, at least one of the gate metal layer or the source-drain metal layer is formed by the steps S10 to S50 provided in the above-mentioned embodiments. Of course, according to design requirements of the array substrate, other film layers may also be used, which is not limited in the present invention.

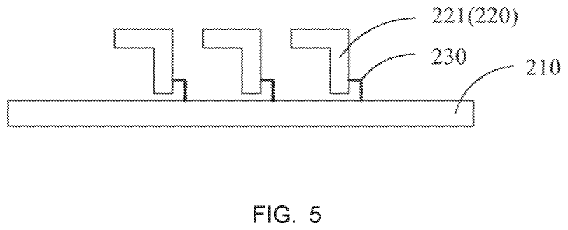

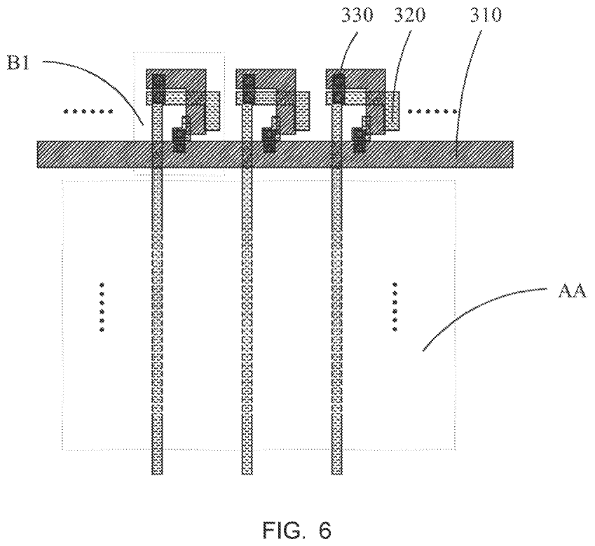

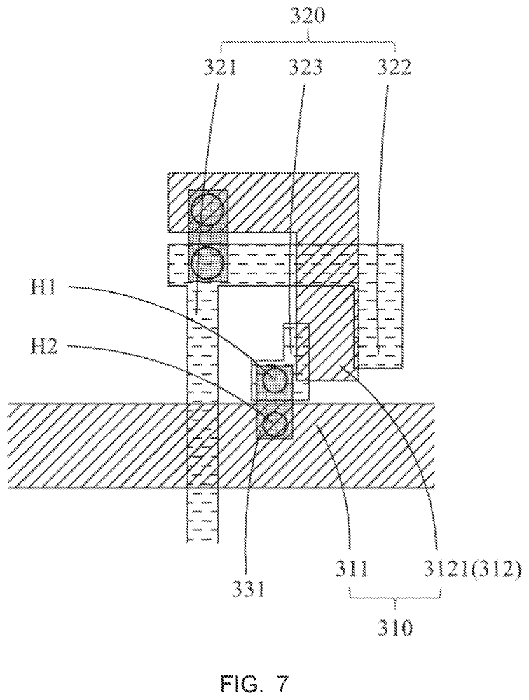

A specific embodiment is given below for further explanation, combining the schematic view of the structure of the photomask used in the method of manufacturing provided in FIG. 3 and the schematic view of the structure of the display panel formed by the method of manufacturing provided in FIG. 5-FIG. 6. FIG. 7 is a partially enlarged structural view of a region B1 in FIG. 6 and detailed description is as follows:

The conductive layer is a gate metal layer formed by the steps S10 to S50. The photomask line of the first conductive portion is a photomask line of an electrostatic sharing electrode line, the photomask line of the second conductive portion is a photomask line of a gate of an electrostatic ring thin film transistor, so that the first conductive portion is the gate of the electrostatic ring thin film transistor, and the second conductive portion is the electrostatic sharing electrode line. That is, as shown in FIG. 5, the photomask comprises:

the photomask line of the electrostatic sharing electrode line 210;

the photomask line of the gate of the electrostatic ring thin film transistor 220 spaced apart from the photomask line of the electrostatic sharing electrode line 210;

a bridging line 230. Two opposite ends of the bridging line 230 are respectively connected to the photomask line of the electrostatic sharing electrode line 210 and the photomask line of the gate of the electrostatic ring thin film transistor 220.

Thus, a formed gate metal layer 310 comprises the electrostatic sharing electrode line 311 and the gate of the electrostatic ring thin film transistor 312, as shown in FIG. 6-FIG. 7 specifically.

In the method of manufacturing provided in this embodiment, the above-mentioned specially designed photomask is used to pattern a first conductive layer, which can effectively reduce risks of abnormal patterns caused by electrostatic damage to the photomask during exposure process. Specifically, the photomask comprises the photomask line of the electrostatic sharing electrode line and the photomask line of the gate of the electrostatic ring thin film transistor that are spaced apart from each other, and the bridging line is further added to connect the photomask line of the electrostatic sharing electrode line and the photomask line of the gate of the electrostatic ring thin film transistor to provide a path for electrostatic discharge, which effectively reduces risks of electrostatic damage due to a small distance between the photomask line of the electrostatic sharing electrode line and the photomask line of the gate of the electrostatic ring thin film transistor, which in turn leads to abnormalities in formed patterns, so as to improve yield of formed array substrate and display panel.

In this embodiment, according to design requirements of the gate metal layer, the photomask line of the gate of the electrostatic ring thin film transistor 220 comprises a plurality of photomask lines of gate islands of the electrostatic ring thin film transistor 221 spaced apart from each other. Each of the photomask lines of the gate islands of the electrostatic ring thin film transistor 221 is connected to the photomask line of the electrostatic sharing electrode line 210 via the bridging lines 230, so that the formed gate of the electrostatic ring thin film transistor 312 in a first conductive layer 310 comprises a plurality of the gate islands of the electrostatic ring thin film transistor 3121 spaced apart from each other.

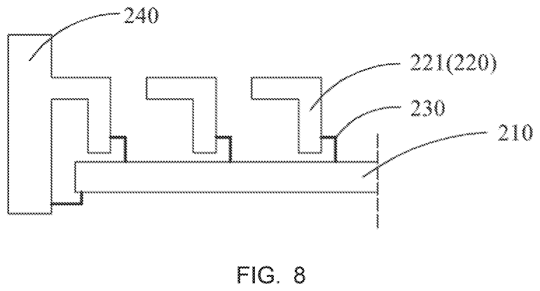

In addition, according to design requirements of a first metal layer, the photomask 200 further comprises photomask lines of other structures. For example, please refer to FIG. 8, the photomask further comprises a photomask line of a peripheral line 240 spaced apart from the photomask line of the electrostatic sharing electrode line 210. The photomask line of the peripheral line 240 is disposed on a side of the photomask line of the electrostatic sharing electrode line 210 and perpendicular to the photomask line of the electrostatic sharing electrode line 210. Generally, both the photomask line of the electrostatic sharing electrode line 210 and the photomask line of the peripheral line 240 of an outer frame region have a shorter distance. Therefore, the above-mentioned bridging line 230 can also be provided between the photomask line of the electrostatic sharing electrode line 210 and the photomask line of the peripheral line 240 to further prevent electrostatic damage from occurring here. It can be understood that the photomask line of the peripheral line 240 is used to form peripheral lines in the first metal layer, usually some peripheral lines for transmitting signals, and its specific function is not limited.

In this embodiment, referring to FIG. 5-FIG. 6, in the formed display panel, the formed source-drain metal layer 320 comprises a plurality of data lines 321 that are parallel to each other and arranged at intervals. The electrostatic sharing electrode line 311 is arranged on a side of a signal input terminal of the data lines and is perpendicular to the data lines. That is, the data lines 321 are arranged in a vertical direction, and the electrostatic sharing electrode line 311 is arranged in a horizontal direction and is arranged outside a side of the signal input terminal corresponding to the data lines in an effective display region AA. Meanwhile, the plurality of the gate islands of the electrostatic ring thin film transistor 3121 that are spaced apart are disposed corresponding to the plurality of data lines 321 in one-to-one correspondence.

In this embodiment, the source-drain metal layer 320 further comprises a plurality of source islands of the electrostatic ring thin film transistor 322 and a plurality of source islands of the electrostatic ring thin film transistor 323 disposed corresponding to the gate islands of the electrostatic ring thin film transistor 3121 in one-to-one correspondence. Each source island of the electrostatic ring thin film transistor 322 is electrically connected to the corresponding data line 321.

In this embodiment, in the formed display panel, the electrode layer 330 comprises a plurality of bridge electrode islands 331 disposed corresponding to the plurality of the source islands of the electrostatic ring thin film transistor 323 in one-to-one correspondence. Each of the drain islands of the electrostatic ring thin film transistor 323 is electrically connected to the corresponding bridge electrode island 331 through a first contact hole H1 in the second insulating layer (not shown in the figure). Each of the bridge electrode islands 331 is electrically connected to the electrostatic sharing electrode line 311 through a second contact hole H2 in the first insulating layer (not shown in the figure) and the second insulating layer. That is, through arrangement of the bridge electrode island 331, an electrical connection between the drain island of the electrostatic ring thin film transistor 323 and the electrostatic sharing electrode line 311 is realized. Similarly, the data line 321 and the gate island of the electrostatic ring thin film transistor 3121 are also electrically connected through another bridge electrode island.

In this embodiment, the method of manufacturing further comprises following steps:

Before forming the first conductive layer, an active layer and a third insulating layer are formed on the substrate, so that the first conductive layer is formed on the third insulating layer; that is, an array substrate with a top gate structure is formed.

Or, before forming the second conductive layer, the active layer and the third insulating layer are formed on the first insulating layer, so that the second conductive layer is formed on the third insulating layer; that is, an array substrate with a bottom gate structure is formed.

Wherein, the active layer comprises a plurality of active islands of the electrostatic ring thin film transistor (not shown in the figure) disposed corresponding to the plurality of the gate islands of the electrostatic ring thin film transistor in one-to-one correspondence.

Through the above-mentioned structural design, each of the gate islands of the electrostatic ring thin film transistor 3121 and the corresponding source island of the electrostatic ring thin film transistor 322, the corresponding drain islands of the electrostatic ring thin film transistor 323, and the corresponding active islands of the electrostatic ring thin film transistor form an electrostatic ring thin film transistor. When the data line 321 generates an extremely large current, the current is transferred to the gate islands of the electrostatic ring thin film transistor 3121 so that the corresponding electrostatic ring thin film transistor is turned on. The current of the data line 321 flows to the electrostatic sharing electrode line 311 through the electrostatic ring thin film transistor to share static electricity.

Another embodiment of the present invention further provides a display panel. The display panel comprises an array substrate, which is formed by the method of manufacturing the array substrate provided in the above-mentioned embodiment. See the description of the above-mentioned embodiment for the specific structure. The display panel can be a liquid crystal display panel, an OLED display panel, a micro-LED display panel, or other display panels using TFT backplane technologies.

In the above-mentioned embodiments, the description of each embodiment has its own focus. For parts that are not described in detail in a certain embodiment, please refer to the detailed description of other embodiments above, which will not be repeated here.

The method of manufacturing the array substrate and the display panel provided by the embodiments of the present invention are described in detail above. In this article, specific examples are used to illustrate the principle and implementation of the present invention. The description of the above embodiments is only used to help understand the method of the present invention and its core idea. Meanwhile, for those skilled in the art, according to the idea of the present invention, there will be changes in the specific implementation and application scope. In summary, the content of the specification should not be construed as limiting the present invention.

1. A photomask, comprising:
a photomask line of a first conductive portion;
a photomask line of a second conductive portion spaced apart from the photomask line of the first conductive portion; and
a bridging line, wherein two opposite ends of the bridging line are respectively connected to the photomask line of the first conductive portion and the photomask line of the second conductive portion;
wherein a width of the bridging line is less than a preset width.

2. The photomask according to claim 1, wherein the photomask line of the first conductive portion comprises a plurality of photomask sub-lines of the first conductive portion spaced apart from each other, and each of the photomask sub-lines of the first conductive portion is connected to the photomask line of the second conductive portion via the bridging line.

3. The photomask according to claim 1, wherein a shape of the bridging line is a straight line, a broken line, or a curved line.

4. The photomask according to claim 1, wherein the width of the bridging line is less than 1.5 microns.

5. The photomask according to claim 4, wherein the width of the bridging line ranges from 0.5 to 1.0 microns.

6. The photomask according to claim 1, wherein the bridging line is a uniform line of equal width.

7. The photomask according to claim 1, wherein the bridging line is a non-uniform line with unequal width, and a width of at least one portion of the bridging line is less than the preset width.

8. A method of manufacturing an array substrate, wherein the method comprises a step of forming a conductive layer on the array substrate, and the step of forming the conductive layer on the array substrate comprises following steps:
S10: forming a metal layer;
S20: forming a photoresist layer on the metal layer;
S30: exposing the photoresist layer under cover of a photomask to form a patterned photoresist layer, wherein the photomask comprises:
a photomask line of a first conductive portion;
a photomask line of a second conductive portion spaced apart from the photomask line of the first conductive portion; and
a bridging line, wherein two opposite ends of the bridging line are respectively connected to the photomask line of the first conductive portion and the photomask line of the second conductive portion, and
a width of the bridging line is less than a preset width;
S40: etching the metal layer to form the conductive layer under cover of the patterned photoresist layer, wherein the conductive layer comprises the first conductive portion and the second conductive portion disposed at intervals; and
S50: stripping and removing the patterned photoresist layer.

9. The method of manufacturing the array substrate as claimed in claim 8, wherein in the step S10, the metal layer is formed by sputtering by a physical vapor deposition process.

10. The method of manufacturing the array substrate according to claim 8, wherein in the step S20, the photoresist layer is formed by a positive photoresist material.

11. The method of manufacturing the array substrate according to claim 8, wherein in the step S30, a shape of the bridging line is a straight line, a broken line, or a curved line.

12. The method of manufacturing the array substrate according to claim 8, wherein the conductive layer is a gate metal layer.

13. The method of manufacturing the array substrate according to claim 8, wherein the conductive layer is a source-drain metal layer.

14. The method of manufacturing the array substrate according to claim 12, wherein in the photomask, the photomask line of the first conductive portion is a photomask line of an electrostatic sharing electrode line, the photomask line of the second conductive portion is a photomask line of a gate of an electrostatic ring thin film transistor, so that the first conductive portion is the gate of the electrostatic ring thin film transistor, and the second conductive portion is the electrostatic sharing electrode line.

15. The method of manufacturing the array substrate according to claim 14, wherein the photomask line of the gate of the electrostatic ring thin film transistor comprises a plurality of photomask lines of gate islands of the electrostatic ring thin film transistor spaced apart from each other, each of the photomask lines of the gate islands of the electrostatic ring thin film transistor is connected to the photomask line of the electrostatic sharing electrode line via the bridging line, so that the formed gate of the electrostatic ring thin film transistor in a first conductive layer comprises the plurality of gate islands of the electrostatic ring thin film transistor spaced apart from each other.

16. The method of manufacturing the array substrate according to claim 14, wherein the photomask further comprises photomask lines of a peripheral line spaced apart from the photomask line of the electrostatic sharing electrode line, and the photomask lines of the peripheral line are connected to the photomask line of the electrostatic sharing electrode line via the bridging line.

17. The method of manufacturing the array substrate according to claim 16, wherein the photomask lines of the peripheral line are disposed on a side of the photomask line of the electrostatic sharing electrode line and perpendicular to the photomask line of the electrostatic sharing electrode line.

18. A display panel, comprising:
an array substrate, wherein the array substrate is formed by the method of manufacturing the array substrate according to claim 8.

19. The display panel according to claim 18, wherein the display panel is a liquid crystal display panel, an organic light-emitting diode (OLED) display panel, or a micro light-emitting diode display panel.
